(19) United States
(12) Patent Application Publication
(10) Pub. No.: US 2025/0105178 A1
(43) Pub. Date: Mar. 27, 2025

(54) SEMICONDUCTOR CHIP AND SEMICONDUCTOR PACKAGE INCLUDING THE SAME, AND MANUFACTURING METHOD OF SEMICONDUCTOR CHIP

(71) Applicant: Samsung Electronics Co., Ltd., Suwon-si (KR)

(72) Inventors: MinKi AHN, Suwon-si (KR); Kwangho LEE, Suwon-si (KR); Heeseok LEE, Suwon-si (KR); Jaegwon JANG, Suwon-si (KR); Heejung CHOI, Suwon-si (KR)

(73) Assignee: Samsung Electronics Co., Ltd., Suwon-si (KR)

(21) Appl. No.: 18/634,322

(22) Filed: Apr. 12, 2024

(30) Foreign Application Priority Data
Sep. 21, 2023 (KR) 10-2023-0126565

(51) Int. Cl. H01L 23/00

(52) U.S. Cl. CPC H01L 24/05; H01L 24/03; H01L 24/08; H01L 24/94; H01L 2224/0218; H01L 2224/0219; H01L 2224/03011; H01L 2224/05565; H01L 2224/08225; H01L 2224/94

(57) ABSTRACT

A semiconductor chip according to an embodiment includes a semiconductor substrate, an interconnection pad on a first surface of the semiconductor substrate, an insulation layer being on the first surface of the semiconductor substrate and defining an opening that exposes at least a partial portion of the interconnection pad, a capping pad being on the insulation layer and being connected to the interconnection pad through the opening, and an insulation structure at a periphery of the capping pad on the insulation layer.

### CROSS-REFERENCE TO RELATED APPLICATION

This U.S. non-provisional patent application claims the benefit and priority under 35 U.S.C. § 119 of Korean Patent Application No. 10-2023-0126565 filed in the Korean Intellectual Property Office on Sep. 21, 2023, the entire contents of which are incorporated herein by reference.

### BACKGROUND

The present disclosure relates to semiconductor chips and semiconductor packages including the same, and manufacturing methods of semiconductor chips.

A semiconductor device may have a small size while performing various functions, and is thus widely used in various electronic industries. As advancements are made in the electronic industry, research on packaging technology has continued to reduce a size of the semiconductor device while also increasing its performance.

Various performance tests may be performed to evaluate a status of a semiconductor chip on a semiconductor substrate before a packaging process. However, due to a structure of a semiconductor chip, the performance tests may not proceed suitably or a life of a test device performing the performance test may be reduced.

### SUMMARY

The present disclosure provides semiconductor chips capable of enhancing performance and productivity and semiconductor packages including the same.

The present disclosure provides manufacturing methods of semiconductor chips capable of enhancing productivity.

A semiconductor chip according to some example embodiments includes a semiconductor substrate, an interconnection pad on a first surface of the semiconductor substrate, an insulation layer being on the first surface of the semiconductor substrate and defining an opening that exposes at least a partial portion of the interconnection pad, a capping pad being on the insulation layer and being connected to the interconnection pad through the opening, and an insulation structure at a periphery of the capping pad on the insulation layer.

A semiconductor package according to some example embodiments includes a redistribution portion, and a semiconductor chip on the redistribution portion. The semiconductor chip according to an embodiment includes a semiconductor substrate, an interconnection pad on a first surface of the semiconductor substrate, an insulation layer being on the first surface of the semiconductor substrate and defining an opening that exposes at least a partial portion of the interconnection pad, a capping pad being on the insulation layer and being connected to the interconnection pad through the opening and to the redistribution portion, and an insulation structure being at a periphery of the capping pad on the insulation layer and being adjacent to the redistribution portion.

A method of manufacturing semiconductor chips according to some example embodiments includes forming a preliminary pad on a first surface of a semiconductor substrate, forming a solder layer on the preliminary pad, performing an electrical die sorting (EDS) process using the solder layer, forming an insulation portion covering the solder layer on the first surface of the semiconductor substrate, and removing the solder layer, an outer portion of the insulation portion, and an outer portion of the preliminary pad.

According to some example embodiments, a pad or a semiconductor chip may be stably protected by an insulation structure. One surface of the semiconductor chip adjacent to a redistribution portion includes a flat surface and thus a yield of a redistribution portion may be enhanced, and a fine pitch may be achieved.

In this instance, in a semiconductor chip that does not include a solder layer in a final structure, a solder layer is formed and a performance test (e.g., an electrical die sorting process) is performed using the solder layer, productivity of the performance test may be enhanced. A pad and an insulation structure respectively having a flat outer surface are formed by a removing process of the solder layer performed after the performance test, thereby enhancing performance of the semiconductor chip. That is, productivity of the semiconductor chip having enhanced performance may be enhanced.

### BRIEF DESCRIPTION OF THE DRAWINGS

FIG. 1 is a cross-sectional view illustrating a semiconductor package according to some example embodiments.

FIG. 2 is a cross-sectional view illustrating a semiconductor chip included in the semiconductor package illustrated in FIG. 1.

FIG. 3 is an enlarged cross-sectional view of a portion A of FIG. 2.

FIG. 4 is a plan view illustrating a first surface of the semiconductor chip illustrated in FIG. 2.

FIG. 5A to FIG. 5F are cross-sectional views illustrating manufacturing methods of a semiconductor chip according to some example embodiments.

FIG. 6A to FIG. 6C are cross-sectional views illustrating manufacturing methods of a semiconductor package according to some example embodiments.

FIG. 7 is a cross-sectional view illustrating a semiconductor chip included in a semiconductor package according to some example embodiments.

FIG. 8 is a plan view illustrating a first surface of the semiconductor chip illustrated in FIG. 7.

FIG. 9A to FIG. 9D are cross-sectional views illustrating a manufacturing method of a semiconductor chip according to some example embodiments.

### DETAILED DESCRIPTION

Example embodiments of the present disclosure will be described more fully hereinafter with reference to the accompanying drawings for those skilled in the art to which the present disclosure pertains to easily practice the present disclosure. The present disclosure may be implemented in various different forms and is not limited to the example embodiments provided herein.

A portion unrelated to the description is omitted in order to clearly describe the present disclosure, and the same or similar components are denoted by the same reference numeral throughout the present specification.

Further, since sizes and thicknesses of portions, regions, members, units, layers, films, etc. illustrated in the accompanying drawings may be arbitrarily shown for better understanding and convenience of explanation, the present disclosure is not limited to the illustrated sizes and thicknesses. In the drawings, thicknesses of portions, regions, members, units, layers, films, etc. may be enlarged or exaggerated for convenience of explanation.

It will be understood that when a component such as a layer, film, region, or substrate is referred to as being “on” another component, it may be directly on other component or an intervening component may also be present. In contrast, when a component is referred to as being “directly on” another component, there is no intervening component present. Further, when a component is referred to as being “on” or “above” a reference component, a component may be positioned on or below the reference component, and does not necessarily be “on” or “above” the reference component toward an opposite direction of gravity.

In addition, unless explicitly described to the contrary, the word “comprise”, “include”, or “contain”, and variations such as “comprises”, “comprising”, “includes”, “including”, “contains” or “containing” will be understood to imply inclusion of other component rather than the exclusion of any other components.

Further, throughout the specification, a phrase “on a plane”, “in a plane”, “on a plan view”, or “in a plan view” may indicate a case where a portion is viewed from above or a top portion, and a phrase “on a cross-section” or “in a cross-section” may indicate when a cross-section taken along a vertical direction is viewed from a side.

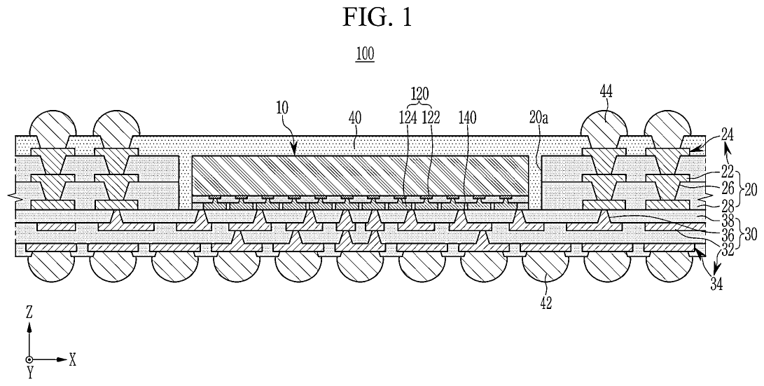

Hereinafter, with reference to FIG. 1 to FIG. 4, semiconductor chips and semiconductor packages including the same according to some example embodiments will be described in detail.

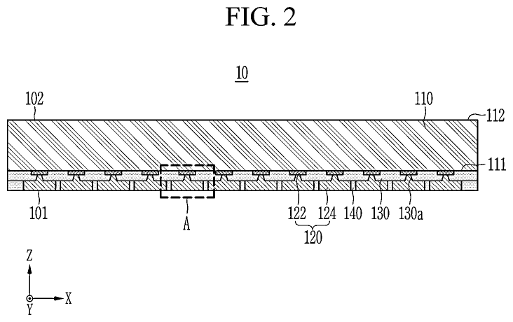

FIG. 1 is a cross-sectional view illustrating a semiconductor package 100 according to some example embodiments, and FIG. 2 is a cross-sectional view illustrating a semiconductor chip 10 included in the semiconductor package 100 illustrated in FIG. 1.

Referring FIG. 1 and FIG. 2, a semiconductor package 100 according to some example embodiments includes a semiconductor chip 10, and a redistribution portion 30 connected to the semiconductor chip 10. The semiconductor package 100 may further include a frame portion 20, a molding portion 40, interconnection members 42 and 44, or the like. This will be described in more detail.

In some example embodiments, the frame portion 20 may include a space portion 20a for providing a space where the semiconductor chip 10 is positioned. The space portion 20a may have a shape of a penetration portion or a penetration hole that penetrates the frame portion 20. However, the example embodiments are not limited thereto.

The frame portion 20 may include a frame redistribution portion constituting a partial portion of a redistribution portion included in the semiconductor package 100. For example, the frame portion 20 or the frame redistribution portion included in the frame portion 20 may include a plurality of redistribution layers 22 with an interlayer insulation layer 28 interposed therebetween, and a contact via 26 connecting the plurality of redistribution layers 22 through penetrating the interlayer insulation layer 28. The redistribution layer 22 and the contact via 26 may be connected to constitute a desired circuit. The contact via 26 may be formed in the same process with the redistribution layer 22, or may be formed in a separate process from the redistribution layer 22.

The interlayer insulation layer 28 may include any of various insulating materials that may electrically insulate wirings that should not be connected. The insulating material may include a thermosetting resin such as an epoxy resin, a thermoplastic resin such as polyimide, a resin including an inorganic filler and/or a glass fiber, or the like. The interlayer insulation layer 28 may include a photosensitive resin such as a photoimageable dielectric (PID) material. When the interlayer insulation layer 28 includes the PID material, each interlayer insulation layer 28 may be thinly formed, the contact via 26 may be finely formed, and the redistribution layer 22 may be easily formed by a plating process. The plurality of interlayer insulation layers 28 may include or be formed of the same material or may include different materials from each other. Depending on a process, an interface between the plurality of interlayer insulation layers 28 might not be clear.

The redistribution layer 22 or the contact via 26 may include any of various conductive materials. At least two of the plurality of the redistribution layers 22 and the contact via 26 may include or be formed of the same material or may include different materials from each other. The redistribution layer 22 or the contact via 26 may include or be formed of a single layer, or may include a plurality of layers. For example, the redistribution layer 22 or the contact via 26 may include at least one of copper, aluminum, tungsten, nickel, gold, tin, manganese, cobalt, titanium, tantalum, ruthenium, and/or beryllium or an alloy including the same.

In some example embodiments, the semiconductor chip 10 may be a non-memory chip for calculating, processing, or controlling information. For example, the semiconductor chip 10 may be an application processor (AP), a power management integrated circuit (PMIC), a radio frequency chip, an application-specific integrated circuit (ASIC), or the like. In some example embodiments, the semiconductor chip 10 may be a central processing unit (CPU), a graphic processing unit (GPU), a neural processing unit (NPU), a micro controller unit (MCU), or the like. In some example embodiments, the semiconductor chip 10 may include a memory chip for storing data. In this instance, the memory chip may be a volatile memory such as a dynamic random access memory (DRAM), a static random access memory (SRAM), or the like, or a non-volatile memory such as a NAND flash memory system. In some example embodiments, the semiconductor chip 10 may include a merged semiconductor chip merging a memory portion and a non-memory portion, or may include a plurality of a chip. Accordingly, the example embodiments are not limited to a type, a kind, or the like of the semiconductor chip 10.

The semiconductor chip 10 may be in the space portion 20a of the frame portion 20. An area of the space portion 20a may be larger than an area of the semiconductor chip 10, and the semiconductor chip 10 may be spaced apart from an inner side surface of the frame portion 20 in the space portion 20a. However, the example embodiments are not limited thereto. Various modifications are possible.

A pad 120 may be at a first surface (for example, a lower surface) 101 of the semiconductor chip 10. The pad 120 may be a portion for connecting the semiconductor chip 10 to the redistribution portion included in the semiconductor package 100. For example, the pad 120 may be redistributed by the frame redistribution portion included in the frame portion 20 and the redistribution portion 30. The semiconductor chip 10 and the pad 120 included in the semiconductor chip 10 will be described later in more detail.

In the description, it is illustrated as an example that one semiconductor chip 10 is in the space portion 20a of the frame portion 20. However, the example embodiments are not limited thereto. An electronic component including any of various active or passive elements may be in the space portion 20a of the frame portion 20. The electronic component, instead of the semiconductor chip 10, may be in the space portion 20a, the electronic component and the semiconductor chip 10 may be in the space portion 20a, or one or the plurality of semiconductor chips 10 may be in the space portion 20a. Other various modifications are possible.

The molding portion 40 may constitute a molding of the semiconductor chip 10. For example, the molding portion 40 may cover or surround the semiconductor chip 10 and/or the frame portion 20. For example, the molding portion 40 may fill a space between the frame portion 20 and the semiconductor chip 10, and in some example embodiments, the molding portion 40 may be additionally on the frame portion 20. According to some example embodiments, the molding portion 40 may include one layer or a plurality of layers. The molding portion 40 may include a thermosetting resin such as an epoxy resin, a thermoplastic resin such as polyimide, a resin including an inorganic filler and/or a glass fiber, an epoxy molding compound (EMC), or the like. A material, a shape, or the like of the molding portion 40 may be variously modified.

In the drawing, it is illustrated as an example embodiment that an upper surface of the semiconductor chip 10 may be lower than an upper surface of the frame portion 20. However, the example embodiments are not limited thereto. For example, the upper surface of the semiconductor chip 10 may be on the same plane as the upper surface of the frame portion 20 or may be higher than the upper surface of the frame portion 20.

In some example embodiments, the redistribution portion 30 may be on a first surface 101 of the semiconductor chip 10. For example, the redistribution portion 30 may be on the frame portion 20, the molding portion 40, and/or the first surface 101 of the semiconductor substate. For reference, the redistribution portion 30 may be referred to as a redistribution substrate, a wiring substrate, a connection substrate, or the like.

The redistribution portion 30 may include a redistribution layer 32 and a contact via 36. The redistribution layer 32 may be on the interlayer insulation layer 38 on the frame portion 20, the molding portion 40, and/or the first surface 111 of the semiconductor substrate 110. The contact via 36 may connect the redistribution layer 32 to the pad 120 of the semiconductor chip 10 and/or the frame redistribution portion included in the frame portion 20 through penetrating the interlayer insulation layer 38. For example, the redistribution layer 32 may include a plurality of redistribution layers 32 positioned with the interlayer insulation layer 38 interposed therebetween, and the contact via 36 may connect the plurality of redistribution layers 32 through penetrating the interlayer insulation layer 38. The redistribution layer 32 and the contact via 36 may be connected to constitute a desired circuit. The contact via 36 may be formed in the same process with the redistribution layer 32, or may be formed in a separate process from the redistribution layer 32.

The redistribution layer 32 may include a first interconnect pad 34 at an outer side of the redistribution portion 30 where a first interconnection member 42 is positioned. The redistribution layer 22 at an outer side of the frame portion 20 may include a second interconnection pad 24 where a second interconnection member 44 is positioned. The first interconnection pad 34 is a portion where the first interconnection member 42 for connection with an external circuit, an external device, or the like is positioned, and the second interconnection pad 24 may be a portion where the second interconnection member 44 is positioned.

The interlayer insulation layer 38 may include any of various insulating materials that may electrically insulate wirings that should not be connected. The insulating material may include a thermosetting resin such as an epoxy resin, a thermoplastic resin such as polyimide, a resin including an inorganic filler and/or a glass fiber, or the like. The interlayer insulation layer 38 may include a photosensitive resin such as a PID material. The plurality of interlayer insulation layers 38 may include or be formed of the same material or may include different materials from each other. Depending on a process, an interface between the plurality of interlayer insulation layers 38 might be not clear.

The redistribution layer 32 or the contact via 36 may include any of various conductive materials. At least two of the plurality of the redistribution layers 32 and the contact via 36 may include or be formed of the same material or may include different materials from each other. The redistribution layer 32 or the contact via 36 may include or be formed of a single layer, or may include a plurality of layers. For example, the redistribution layer 32 or the contact via 36 may include at least one of copper, aluminum, tungsten, nickel, gold, tin, manganese, cobalt, titanium, tantalum, ruthenium, and/or beryllium or an alloy including the same. For example, a first interconnection pad 34 or a second interconnection pad 24 may include copper, but the example embodiments are not limited thereto.

In the description, the redistribution portion 30 may be on the first surface 101 of the semiconductor chip 10 as an example, but the example embodiments are not limited thereto. The redistribution portion 30 may be on a second surface (e.g., an upper surface) 102 of the semiconductor chip 10. In some example embodiments, the redistribution portion 30 may include a first redistribution portion on the first surface 101 of the semiconductor chip 10 and a second redistribution portion on the second surface 102 of the semiconductor chip 10. In the case that the redistribution portion 30 is on the second surface 102 of the semiconductor chip 10, the second interconnection pad 24 may be in an outmost redistribution layer among the redistribution layers on the second surface 102 of the semiconductor chip 10.

The semiconductor package 100 may be connected to a package substrate by a first interconnection member 42, and the semiconductor package 100 may be connected to another electronic component, semiconductor chip, or the like by a second interconnection member 44. However, the example embodiments are not limited thereto. Various modifications are possible.

The first interconnection member 42 or the second interconnection member 44 may have a land shape, a ball shape, or a pin shape. The first interconnection member 42 or the second interconnection member 44 may include at least one of tin, lead, bismuth, silver, copper, aluminum, tungsten, nickel, manganese, cobalt, titanium, tantalum, ruthenium, beryllium, indium, molybdenum, magnesium, rhenium, and/or gallium or an alloy including the same. For example, the first interconnection member 42 or the second interconnection member 44 may include tin or an alloy including tin (as an example, a Sn—Ag alloy or a Sn—Ag—Cu alloy). However, the example embodiments are not limited thereto, and a shape, a material, or the like of the first interconnection member 42 or the second interconnection member 44 may be variously modified.

The frame redistribution portion included in the frame portion 20 and the redistribution portion 30 may be connected to constitute a desirable circuit, thereby constituting the redistribution portion of the semiconductor package 100. The redistribution portion may perform various functions according to a design. For example, the redistribution portion may include a ground pattern, a power pattern, and a signal pattern. The signal pattern may be or include a pattern for transmitting various signals, e.g., data signals, or the like, except for signals applied to the ground pattern, the power pattern, or the like. The contact via 26 or the contact via 36 included in the redistribution portion may include a contact via for ground, a contact via for power, a contact via for signal, or the like.

For example, the frame redistribution portion included in the frame portion 20 and the redistribution portion 30 may form a fan-out structure that redistributes the pad 120 of the semiconductor chip 10 to a fan-out region, or electrically connect a plurality of chips constituting the semiconductor chip 10. The fan-out region may mean a region that does not overlap with the semiconductor chip 10 when viewed in a plan view. When the fan-out structure is formed by the redistribution portion, a region where the first interconnection pad 34 or the first interconnection member 42 connected to the interconnection pad 34 may be larger than a region where the semiconductor chip 10 is positioned. Thus, while reducing a size of the semiconductor chip 10, a sufficient number of the first interconnection pads 34 or the first interconnection members 42 may be provided. However, the example embodiments are not limited thereto, and various modifications are possible. As an example, the redistribution portion may form a fan-in structure.

For example, the semiconductor package 100 according to some example embodiments may be a fan-out panel level package (FOPLP) having a fan-out structure formed by using the redistribution portion, and the semiconductor chip 10 included in the semiconductor package 100 may be a semiconductor chip for a fan-out panel level package. In some example embodiments, the semiconductor package 100 according to some example embodiments may be a fan-out wafer level package (FOWLP) having a fan-out structure formed by using the redistribution portion, and the semiconductor chip 10 included in the semiconductor package 100 may be a semiconductor chip for a fan-out wafer level package. The semiconductor package 100 according to some example embodiments and the semiconductor chip 10 included in the semiconductor package 100 may have other various structures.

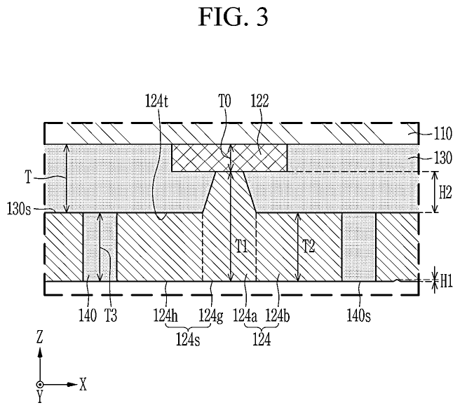

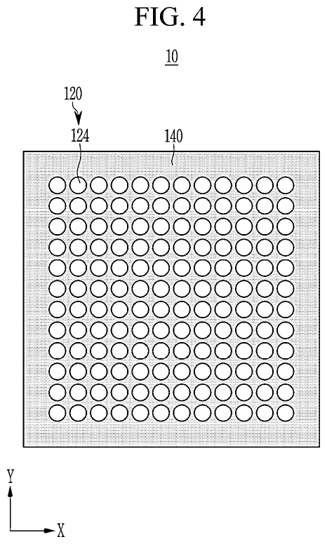

Referring to FIG. 3 and FIG. 4, together with FIG. 2, the semiconductor chip 10 included in the semiconductor package 100 according to the example embodiments will be described in more detail. FIG. 3 is an enlarged cross-sectional view of a portion A of FIG. 2. FIG. 4 is a plan view illustrating the first surface 101 of the semiconductor chip 10 illustrated in FIG. 2.

Referring FIG. 2 to FIG. 4, the semiconductor chip 10 according to some example embodiments may include a semiconductor substrate 110, an interconnection pad 122, an insulation layer 130, a capping pad 124, and an insulation structure 140 on the first surface 111 of the semiconductor substrate 110. Here, the interconnection pad 122 and the capping pad 124 may constitute the pad 120 of the semiconductor chip 10.

For example, the semiconductor substrate 110 may include a semiconductor material, such as silicon (Si) or germanium (Ge), or may include a compound semiconductor material, such as silicon carbide (SiC), gallium arsenide (GaAS), indium arsenide (InAs), indium phosphide (InP), or the like. The semiconductor substrate 110 may include a conductive region (e.g., a well doped with a dopant), or include an insulation structure such as shallow trench isolation (STI).

A semiconductor device portion including various circuit elements may be on the first surface 111 of the semiconductor substrate 110. The circuit elements may include an active element, such as a transistor or the like, or a passive element, such as a capacitor, a resistor, an inductor or the like. The semiconductor device portion may further include a conductive wiring or a conductive plug configured to electrically connect the circuit elements, and an insulation layer insulate the conductive wiring, the conductive plug, and/or the circuit elements that should not be connected. The first surface 111 of the semiconductor substrate 110 may face the redistribution portion 30.

The interconnection pad 122 may be on the first surface 111 of the semiconductor substrate 110. The insulation layer 130 may be on the first surface 111 of the semiconductor substrate 110 and include or define an opening 130a exposing at least a partial portion of the interconnection pad 122. The capping pad 124 may be on the insulation layer 130 and be connected to the interconnection pad 122 through the opening 130a, and the insulation structure 140 may be at a periphery of the capping pad 124 on the insulation layer 130.

For example, the insulation layer 130 may include the opening 130a at a central region of the interconnection pad 122, and may cover an edge region of the interconnection pad 122 and the first surface 111 of the semiconductor substrate 110. Accordingly, the insulation layer 130 may protect the semiconductor substrate 110 and the interconnection pad 122.

The insulation layer 130 may include any of various compounds or any of various resins. For example, the insulation layer 130 may include a passivation layer including an insulating material of the compound, such as oxide, nitride, oxynitride, or the like. In some example embodiment, the insulation layer 130 may include a resin insulation layer including any of various resins. In this instance, the insulation layer 130 may include a thermosetting resin such as an epoxy resin, a thermoplastic resin such as polyimide, a resin including an inorganic filler and/or a glass fiber, or the like. The insulation layer 130 may include a photosensitive resin such as a photoimageable dielectric (PID) material. In some example embodiments, the insulation layer 130 may include the passivation layer including the insulating material of the compound, and the resin insulation layer on the passivation layer. That is, the insulation layer 130 may include various materials or various stacking structures. The insulation layer 130 may include a single layer or a plurality of layers. In a case that the insulation layers 130 include the plurality of layers, an interface between the plurality of layers might not be clear.

In some example embodiment, the insulation structure 140 at the periphery of the capping pad 124 may be at least at an edge region of the semiconductor chip 10. Thereby, the edge region of the semiconductor chip 10 may be reinforced or protected. For example, the insulation structure 140 may protect the edge region of the semiconductor chip 10 in a cutting process. The insulation structure 140 may prevent, suppress, or reduce in likelihood the molding portion 40 from flowing into the capping pad 124 in a packaging process of the semiconductor chip 10. The insulation structure 140 may be referred to as an insulation dam, an insulation barrier, an insulation partition, or the like.

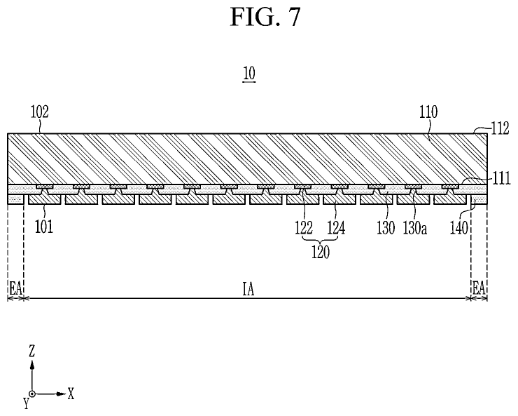

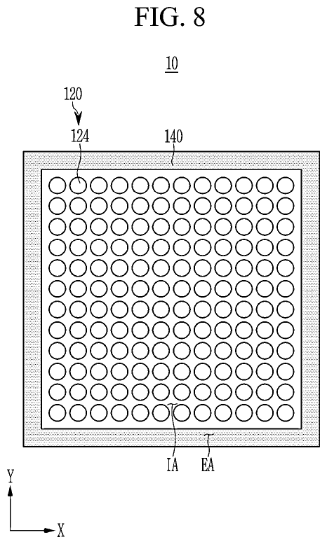

For example, the insulation structure 140 may be at an entire region other than the capping pad 124 on the insulation layer 130. That is, the insulation structure 140 may be at the entire region where the capping pad 124 is not positioned at the periphery of the capping pad 124. Accordingly, in a plan view, the first surface 101 of the semiconductor chip 10 may be formed of an outer surface 124s of the capping pad 124 and an outer surface 140s of the insulation structure 140. Therefore, the insulation structure 140 may stably protect the capping pad 124, and stability in a forming of the redistribution portion 30 may be enhanced more. A modified example embodiment will be described later in more detail with reference to FIG. 7 and FIG. 8.

The insulation structure 140 may include a photosensitive material such as a photoimageable dielectric (PID) material, or an epoxy mold compound (EMC). For example, the photosensitive material may include photosensitive polyimide (PSPI), or the like, but the example embodiments are not limited thereto. When the insulation structure 140 includes the photosensitive material, a patterning process may be easy, and chemical resistance, reliability, or the like may be enhanced. When the insulation structure 140 includes the epoxy mold compound, the capping pad 124 may be stably protected. However, the example embodiments are not limited thereto. A material of the insulation structure 140 may be variously modified.

The capping pad 124 being on the insulation layer 130 may be stably connected to the interconnection pad 122 through the opening 130a of the insulation layer 130. The capping pad 124 being on the insulation layer 130 and connected to the interconnection pad 122 through the opening 130a may be referred to as a pillar pad.

The interconnection pad 122 and the capping pad 124 may include any of various conductive materials. For example, the interconnection pad 122 or the capping pad 124 may include at least one of copper, aluminum, tungsten, nickel, gold, tin, manganese, cobalt, titanium, tantalum, ruthenium, and beryllium or an alloy including the same. In this instance, the interconnection pad 122 may include a material being able to be easily manufactured in a manufacturing process of the circuit elements, the conductive wirings, or the like formed on the first surface 111 of the semiconductor substrate 110 in the manufacturing of the semiconductor chip 10. The capping pad 124 may include a material suitable to be connected to the redistribution portion 30. For example, the interconnection pad 122 may include aluminum, and the capping pad 124 may include a metal being able to be formed by electrolytic plating (e.g., copper, nickel, molybdenum, or the like).

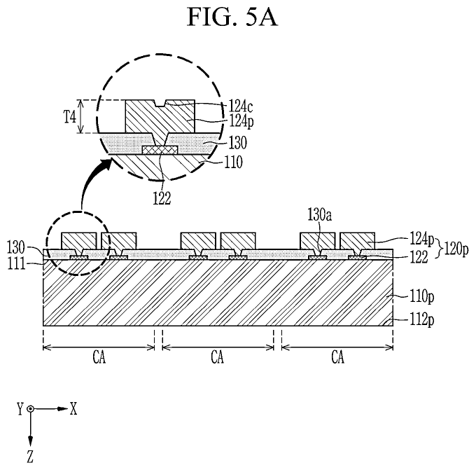

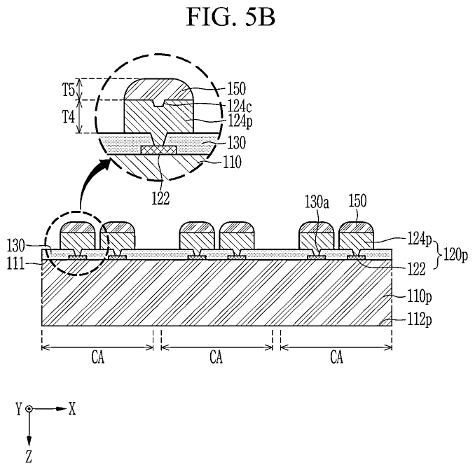

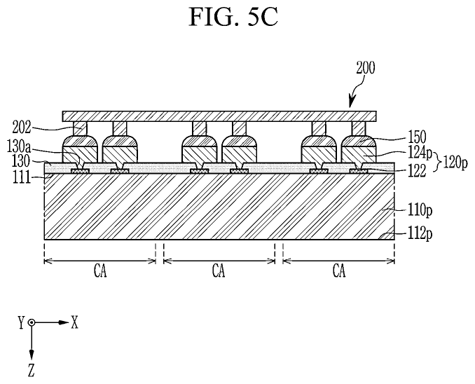

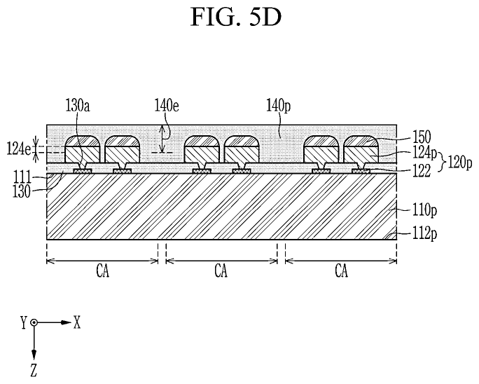

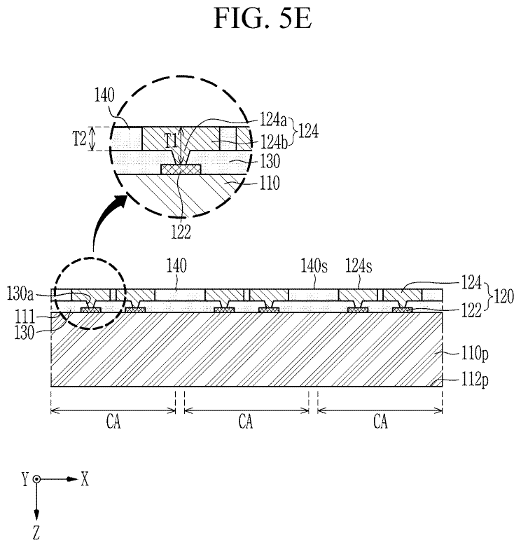

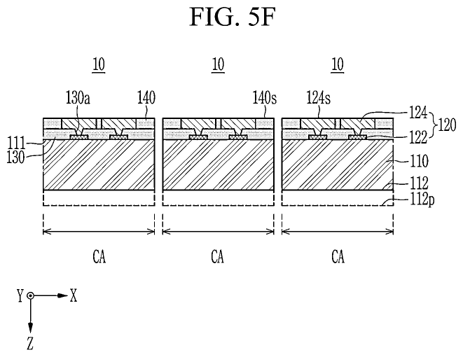

The capping pad 124 may include a first portion 124a filling the opening 130a and connected to the interconnection pad 122, and a second portion 124b on the insulation layer 130. In some example embodiments, a first outer surface 124g of the first portion 124a and a second outer surface 124h of the second portion 124b may be substantially at the same height or may be substantially on the same plane. Therefore, the outer surface 124s of the capping pad 124 may include or be formed of a flat surface. Accordingly, in some example embodiments, the outer surface 124s of the capping pad 124 might not include a dimple 124c (refer to FIG. 5A) that might be at the outer surface 124s of the capping pad 124.

For example, a height variation H1 at the outer surface 124s of the capping pad 124 may be 1 μm or less (e.g., 0.5 μm or less). Here, the height variation H1 at the outer surface 124s of the capping pad 124 may mean a height variation, for example a maximum height variation or a maximum height difference, existing in the outer surface 124s in a thickness direction of the semiconductor chip 10 (a Z-axis direction in the drawing). For example, a height difference between the first outer surface 124g of the first portion 124a and the second outer surface 124h of the second portion 124b may be 1 μm or less (e.g., 0.5 μm or less). When the height variation H1 at the outer surface 124s of the capping pad 124 is 1 μm or less (e.g., 0.5 μm or less), the outer surface 124s of the capping pad 124 may be considered to include or be formed of a flat surface. In FIG. 3, it is illustrated as an example that a partial portion of the outer surface 124s of the capping pad 124 is on a plane that is slightly different from the other portion of the outer surface 124s of the capping pad 124 to illustrate the height variation H1 at the outer surface 124s of the capping pad 124. This is for the description and the example embodiments are not limited thereto.

For example, the height variation H1 at the outer surface 124s of the capping pad 124 may be smaller than a thickness TO of the interconnection pad 122 or a thickness T of the insulation layer 130. Here, the thickness TO of the interconnection pad 122 or the thickness T of the insulation layer 130 may be a thickness, for example a maximum thickness, in a thickness direction of the semiconductor chip 10 (a Z-axis direction in the drawing). For example, the first outer surface 124g of the first portion 124a may be at a position protruding to an outside than the outer surface 130s of the insulation layer 130.

In some example embodiments, the outer surface 124s of the capping pad 124 may be a flatter surface than an inner surface 124t of the capping pad 124 adjacent to the insulation layer 130 and the interconnection pad 122. By the thickness T of the insulation layer 130, a height variation H2 at the inner surface 124t of the capping pad 124 may be relatively large. For example, the height variation H1 at the outer surface 124s of the capping pad 124 may be smaller than the height variation H2 at the inner surface 124t of the capping pad 124. Here, the height variation H2 at the inner surface 124t of the capping pad 124 may be a height variation, for example maximum height variation or a maximum height difference, existing in the inner surface 124t in a thickness direction of the semiconductor chip 10 (a Z-axis direction in the drawing).

Thereby, a first thickness T1 of the first portion 124a may be larger than a second thickness T2 of the second portion 124b. Here, the first thickness T1 or the second thickness T2 may mean a thickness, for example a maximum thickness, in a thickness direction of the semiconductor chip 10 (a Z-axis direction in the drawing). This differs from the conventional capping pad formed by electrolytic plating and having a substantially uniform thickness in an entire region.

In some example embodiments, the outer surface 140s of the insulation structure 140 and the outer surface 124s of the capping pad 124 may be substantially at the same height or may be substantially on the same plane. In this instance, the outer surface 140s of the insulation structure 140 may include or be formed of a flat surface.

For example, a height variation at the outer surface 140s of the insulation structure 140 may be 1 μm or less (e.g., 0.5 μm or less). Here, the height variation at the outer surface 140s of the insulation structure 140 may be a height variation, for example, a maximum height variation or a maximum height difference, existing in the outer surface 140s in a thickness direction of the semiconductor chip 10 (a Z-axis direction in the drawing). When the height variation at the outer surface 140s of the insulation structure 140 is 1 μm or less (e.g., 0.5 μm or less), the outer surface 140s of the insulation structure 140 may be considered to include or be formed of a flat surface.

For example, a height difference between the outer surface 140s of the insulation structure 140 and the outer surface 124s of the capping pad 124 may be 1 μm or less. Here, the height difference between the outer surface 140s of the insulation structure 140 and the outer surface 124s of the capping pad 124 may mean a height difference, for example a maximum height difference, between the outer surface 140s of the insulation structure 140 and the outer surface 124s of the capping pad 124 in a thickness direction of the semiconductor chip 10 (a Z-axis direction in the drawing). When the height difference between the outer surface 140s of the insulation structure 140 and the outer surface 124s of the capping pad 124 is 1 μm or less (e.g., 0.5 μm or less), the outer surface 140s of the insulation structure 140 and the outer surface 124s of the capping pad 124 may be considered to be substantially on the same plane.

For example, the height difference between the outer surface 140s of the insulation structure 140 and the outer surface 124s of the capping pad 124 may be smaller than the thickness TO of the interconnection pad 122 or the thickness T of the insulation layer 130.

In FIG. 3, it is illustrated as an example that a partial portion of the outer surface 124s of the capping pad 124 is on a plane that is slightly different from of the outer surface 140s of the insulation structure 140 to illustrate the height difference. This is for the description and the example embodiments are not limited thereto.

In some example embodiments, the outer surface 140s of the insulation structure 140 and the outer surface 124s of the capping pad 124 may have the same surface properties. For example, the outer surface 140s of the insulation structure 140 and the outer surface 124s of the capping pad 124 may have a grinding wheel mark of the same or similar pattern, or may have the same or similar surface roughness (e.g., the surface roughness with a difference less than 10%).

The height variation H1 at the outer surface 124s of the capping pad 124, the height difference between the first portion 124a and the second portion 124b in the capping pad 124, the height variation at the outer surface 140s of the insulation structure 140, the height difference between the outer surface 124s of the capping pad 124 and the outer surface 140s of the insulation structure 140, the surface properties of the outer surface 140s of the insulation structure 140 and the outer surface 124s of the capping pad 124 may be due to a manufacturing process of the semiconductor chip 10. For example, the outer surface 140s of the insulation structure 140 and the outer surface 124s of the capping pad 124 may be formed by the same grinding process. This will be described in more detail later in a manufacturing process of the semiconductor chip 10.

In some example embodiments, the capping pad 124 may have a relatively large thickness.

For example, the first thickness T1 of the first portion 124a of the capping pad 124 may be larger than the thickness TO of the interconnection pad 122 or the thickness T of the insulation layer 130. For example, the first thickness T1 of the first portion 124a of the capping pad 124 may be larger than a sum of the thickness TO of the interconnection pad 122 and the thickness T of the insulation layer 130. The second thickness T2 of the second portion 124b of the capping pad 124 may be larger than the thickness TO of the interconnection pad 122 or the thickness T of the insulation layer 130. For example, the second thickness T2 of the second portion 124b of the capping pad 124 may be larger than the sum of the thickness TO of the interconnection pad 122 and the thickness T of the insulation layer 130. In some example embodiments, the second thickness T2 of the second portion 124b of the capping pad 124 may be the same as or smaller than the sum of the thickness TO of the interconnection pad 122 and the thickness T of the insulation layer 130.

For example, a thickness of the capping pad 124 (e.g., the second thickness T2 of the second portion 124b) may be 5 μm to 15 μm. When the capping pad 124 (e.g., the second portion 124b) has a sufficient thickness as in the above, stability of a manufacturing process may be enhanced. If the thickness of the capping pad 124 (e.g., the second thickness T2 of the second portion 124b) is smaller than 5 μm, the stability of the manufacturing process may be deteriorated. If the thickness of the capping pad 124 (e.g., the second thickness T2 of the second portion 124b) is larger than 15 μm, a process time or a process cost may increase. However, the example embodiments are not limited thereto. In some example embodiments, the second thickness T2 of the second portion 124b may be smaller than 5 μm or may be larger than 15 μm.

In some example embodiments, a ratio (T2/T0) of the thickness of the capping pad 124 (e.g., the second thickness T2 of the second portion 124b) to the thickness TO of the interconnection pad 122 may be 2 to 20. However, the example embodiments are not limited thereto. In some example embodiments, the ratio (T2/T0) may be smaller than 2 or may be larger than 20.

Thereby, the capping pad 124 has a relatively large thickness and thus an electrical connection property with the redistribution portion 30 may be enhanced. In a manufacturing process including a removing process of a partial portion of the capping pad 124, the capping pad 124 has the relatively large thickness and thus stability of the removing process may be enhanced. The interconnection pad 122 has relatively small thickness and thus cost and time of a manufacturing process may be reduced.

As in the above, the second portion 124b of the capping pad 124 and the insulation structure 140 are on the insulation layer 130, and the outer surface 124s of the capping pad 124 and the outer surface 140s of the insulation structure 140 may be substantially on the same plane. Therefore, a thickness T3 of the insulation structure 140 may be substantially the same as the second thickness T2 of the second portion 124b of the capping pad 124. Here, the thickness T3 of the insulation structure 140 may be a thickness, for example a maximum thickness, in a thickness direction of the semiconductor chip 10 (a Z-axis direction in the drawing).

For example, a difference between the thickness T3 of the insulation structure 140 and the second thickness T2 of the second portion 124b of the capping pad 124 may be 1 μm or less (e.g., 0.5 μm or less). Accordingly, the thickness T3 of the insulation structure 140 may be larger than the thickness TO of the interconnection pad 122 or the thickness T of the insulation layer 130. For example, the thickness T3 of the insulation structure 140 may be larger than the sum of the thickness TO of the interconnection pad 122 and the thickness T of the insulation layer 130. In some example embodiments, the thickness T3 of the insulation structure 140 may be the same as or smaller than the sum of the thickness TO of the interconnection pad 122 and the thickness T of the insulation layer 130.

For example, the thickness T3 of the insulation structure 140 may be 5 μm to 15 μm. However, the example embodiments are not limited thereto. In some example embodiments, the thickness T3 of the insulation structure 140 may be smaller than 5 μm or may be larger than 15 μm. In some example embodiments, a ratio (T3/T0) of the thickness T3 of the insulation structure 140 to the thickness TO of the interconnection pad 122 may be 2 to 20. However, the example embodiments are not limited thereto. In some example embodiments, the ratio (T3/T0) may be smaller than 2 or may be larger than 20.

The outer surface 124s of the capping pad 124 and the outer surface 140s of the insulation structure 140 may be adjacent to the redistribution portion 30. More particularly, the outer surface 124s of the capping pad 124 and the outer surface 140s of the insulation structure 140 may be in contact with the redistribution portion 30. The first surface 101 of the semiconductor chip 10 adjacent to or in contact with the redistribution portion 30 includes a flat surface and thus a yield of the redistribution portion 30 may be enhanced and a fine pitch may be achieved.

According to some example embodiments, the pad 120 (e.g., the capping pad 124) or the semiconductor chip 10 may be stably protected by the insulation structure 140. The first surface 101 of the semiconductor chip 10 adjacent to or in contact with the redistribution portion 30 includes a flat surface and thus a yield of the redistribution portion 30 may be enhanced and the fine pitch may be achieved. In addition, time and cost of a performance test (e.g., an electrical die sorting process) in a manufacturing process may be reduced, thereby enhancing productivity. This will be described in more detail in a manufacturing process of the semiconductor chip 10.

In the drawings, it is illustrated as an example that the semiconductor chip 10 has the same length in a first direction (an X-axis direction in the drawing) and in a second direction (a Y-axis direction in the drawing), and an inner region where the capping pad 124 is positioned is at a central portion of the semiconductor chip 10 to have a symmetrical structure. It is illustrated as an example that the semiconductor chip 10 is at a central portion of the semiconductor package 100 to have a symmetrical structure. However, a shape of the semiconductor chip 10, a shape of the semiconductor package 100, an arrangement of the semiconductor chip 10, or the like may be variously modified.

A manufacturing method of a semiconductor chip 10 included in a semiconductor package 100 will be described in detail with reference to FIG. 5A to FIG. 5F.

FIG. 5A to FIG. 5F are cross-sectional views illustrating a manufacturing method of a semiconductor chip according to some example embodiments. In FIG. 5A to FIG. 5F, it is illustrated as an example that a plurality of semiconductor chips 10 are formed to correspond to a plurality of chip regions CA on a preliminary semiconductor substrate 110p, and then, a plurality of semiconductor chip 10 are formed by a cutting process of a semiconductor substrate 110. For simple illustration and a clear understanding, a semiconductor chip 10 in the chip region CA is simply illustrated in FIG. 5A to FIG. 5F and thus a size, a ratio, or the like of the semiconductor chip 10 illustrated in FIG. 5A to FIG. 5F may be different from a size, a ratio, or the like of the semiconductor chip 10 illustrated in FIG. 2.

First, as illustrated in FIG. 5A, an interconnection pad 122, an insulation layer 130, and a preliminary capping pad 124p may be formed on a first surface 111 of a preliminary semiconductor substrate 110p. The interconnection pad 122 and the preliminary capping pad 124p may be referred to as a preliminary pad 120p. Thereby, a plurality of chip portions (e.g., a plurality of semiconductor chips 10 (refer to FIG. 5F)) corresponding to a plurality of chip regions CA may be formed on the preliminary semiconductor substrate 110p.

For a process of forming the interconnection pad 122, the insulation layer 130, and the preliminary capping pad 124p, various processes may be applied. For example, the interconnection pad 122 may be formed by a deposition process, a plating process, or the like. The insulation layer 130 may be formed by a deposition process, a coating process, or the like. The preliminary capping pad 124p may be formed by a plating process (e.g., an electrolytic plating process), or the like. Various other processes may be applied.

In this instance, the preliminary capping pad 124p may have a uniform thickness T4 in an entire region. By the plating process, a thickness T4 of a first portion of the preliminary capping pad 124p in the opening 130a of the insulation layer 130 may be substantially the same as a thickness T4 of a second portion of the preliminary capping pad 124p on the insulation layer 130. As illustrated in an enlarged view of FIG. 5A, a dimple 124c may be provided on an outer surface of the preliminary capping pad 124p.

In this instance, the thickness T4 of the preliminary capping pad 124p may be 10 μm to 30 μm. The thickness range may be determined such that an outer surface of a capping pad 124 (refer to FIG. 5E) includes a flat surface and the capping pad 124 has a predetermined thickness (e.g., 5 μm to 15 μm) after a removing process of an outer portion 124e (refer to FIG. 5D) of the preliminary capping pad 124p. However, the example embodiments are not limited thereto. The thickness T4 of the preliminary capping pad 124p may be variously modified.

Subsequently, as illustrated in FIG. 5B, a solder layer 150 may be formed on the preliminary pad 120p (e.g., the preliminary capping pad 124p). The solder layer 150 may be formed by various processes, for example, by a plating process (e.g., an electrolytic plating process). Various other processes may be applied.

The solder layer 150 may include a portion having a flat surface or have an entirely rounded surface by a reflow process. The solder layer 150 may include at least one of tin, lead, bismuth, silver, copper, aluminum, tungsten, nickel, manganese, cobalt, titanium, tantalum, ruthenium, beryllium, indium, molybdenum, magnesium, rhenium, and/or gallium or an alloy including the same. For example, the solder layer 150 may include tin or an alloy including tin (as an example, a Sn—Ag alloy or a Sn—Ag—Cu alloy). However, the example embodiments are not limited thereto, and a shape, a material, or the like of the solder layer 150 may be variously modified.

A thickness T5 of the solder layer 150 may be 5 μm to 20 μm. For example, the thickness T5 of the solder layer 150 may be smaller than the thickness T4 of the preliminary capping pad 124p. Thereby, structural stability may be enhanced and a material cost may be reduced. In some example embodiments, the thickness T5 of the solder layer 150 may be smaller than 5 μm or larger than 20 μm, or the thickness T5 of the solder layer 150 may be the same as or larger than the thickness T4 of the preliminary capping pad 124p. Other various modifications are possible.

Subsequently, as illustrated in FIG. 50, an electrical die sorting (EDS) process may be performed using the solder layer 150. For example, the electrical die sorting process may be formed by contacting a probe pin 202 of a probe device 200 performing the electrical die sorting process to the solder layer 150. The electrical die sorting process examines a defect of the semiconductor chip 10 in a state that the plurality of semiconductor chips 10 are on the preliminary semiconductor substrate 110p. For example, the probe device 200 including the probe pin 202 may be a probe card including the probe pin 202.

The semiconductor chip 10 for a fan-out panel level package does not include a solder layer, a solder member, a solder bump, or the like in a final structure. In some example embodiments, in the semiconductor chip 10 that does not include the solder layer, the solder member, the solder bump, or the like in the final structure, the solder layer 150 is formed and the electrical die sorting process is performed using the solder layer 150. Then, the electrical die sorting process is performed to the solder layer 150 having the flat surface or the rounded surface, instead of the preliminary capping pad 124p having the dimple 124c. Accordingly, a process difficulty may be lowered and the process time may be reduced. In addition, the electrical die sorting process may be performed using the solder layer 150 having a relatively small strength or hardness than the preliminary capping pad 124p or a capping pad 124 or having a relatively large malleability or ductility than the preliminary capping pad 124p or the capping pad 124. Thus, life of the probe pin 202 or the probe device 200 may be increased. For example, the time of the electrical die sorting process may be reduced, for example by approximately 7-8%, and the life of the probe pin 202 or the probe device 200 may be increased, for example by approximately 50%.

Further, the probe pin 202 or the probe device 200 which was used to a solder layer may be used as it is, and thus, a separate probe pin or probe device for a pad (e.g., the preliminary capping pad 124p) might not be necessary. Thereby, productivity of the electrical die sorting process may be enhanced.

Subsequently, as illustrated in FIG. 5D, an insulation portion 140p may cover the solder layer 150 on the first surface 111 of the preliminary semiconductor substrate 110p. For example, the insulation portion 140p may entirely cover the insulation layer 130 and the solder layer 150 on the first surface 111 of the preliminary semiconductor substrate 110p. The insulation portion 140p may be formed by various methods, for example, by a coating process. For example, the insulation portion 140p may be formed by coating a photosensitive material or an epoxy mold compound.

Subsequently, as illustrated in FIG. 5E, the solder layer 150, a partial portion of the insulation portion 140p (refer to FIG. 5D), and a partial portion of the preliminary pad 120p (refer to FIG. 5D) may be removed. More particularly, an entire portion of the solder layer 150 may be removed, an outer portion 140e (refer to FIG. 5D) of the insulation portion 140p and an outer portion 124e (refer to FIG. 5D) of the preliminary pad 120p may be removed. The outer portion 140e of the insulation portion 140p may be a partial portion of the insulation portion 140p positioned at an outer side in a thickness direction of the preliminary semiconductor substrate 110p (a Z-axis direction in the drawing). The outer portion 124e of the preliminary pad 120p may be a partial portion of the preliminary pad 120p positioned at an outer side in a thickness direction of the preliminary semiconductor substrate 110p (a Z-axis direction in the drawing).

In this instance, the removing process of the solder layer 150, the outer portion 140e of the insulation portion 140p, and the outer portion 124e of the preliminary pad 120p may be performed by a grinding process. When the grinding process is used, the solder layer 150 may be stably removed, and the outer portion 140e of the insulation portion 140p and the outer portion 124e of the preliminary pad 120p may be removed to form an insulation structure 140 having an outer surface 140s of a flat surface and a pad 120 (e.g., a capping pad 124) having an outer surface 124s of a flat surface. For example, the capping pad 124 may include a first portion 124a having a first thickness T1 and a second portion 124b having a second thickness T2, and the outer surface 124s of the capping pad 124 does not has the dimple 124c (refer to FIG. 5B).

The outer surface 140s of the insulation structure 140 and the outer surface 124s of the pad 120 may be formed by the same removing process (e.g., the same grinding process). Thereby, the outer surface 140s of the insulation structure 140 and the outer surface 124s of the pad 120 may be substantially on the same plane. The outer surface 140s of the insulation structure 140 and the outer surface 124s of the pad 120 may have substantially the same surface properties. For example, the outer surface 140s of the insulation structure 140 and the outer surface 124s of the capping pad 124 may have the grinding wheel mark of the same or similar pattern, or may have the same or similar surface roughness (e.g., surface roughness with a difference less than 10%). In some example embodiments, a removing process configured to remove the grinding wheel mark at the outer surface 140s of the insulation structure 140 and the outer surface 124s of the capping pad 124 may be performed.

Subsequently, as illustrated in FIG. 5F, a backlap process configured to reduce a thickness of the preliminary semiconductor substrate 110p (refer to FIG. 5E) may be performed to form a semiconductor substrate 110, and the semiconductor substrate 110 is cut to form a plurality of semiconductor chips 10.

In the backlap process, a grinding process, a polishing process, an abrasion process, or the like may be performed to a preliminary surface 112p of the preliminary semiconductor substrate 110p to adjust a thickness of the semiconductor substrate 110 included in the semiconductor chip 10 to have a predetermined value. For a clear understanding, in FIG. 5F, the preliminary surface 112p of the preliminary semiconductor substrate 110p is illustrated as a dotted line, and a second surface 112 of the semiconductor substrate 110 formed by the backlap process is illustrated as a solid line.

In the cutting process of the semiconductor substrate 110, the semiconductor substrate 110 is cut along a cut region between the plurality of chip regions CA to form the plurality of semiconductor chips 10. For the cut process of the semiconductor substrate, various processes may be applied.

According to some example embodiments, in the semiconductor chip 10 that does not include the solder layer 150 in a final structure, the solder layer 150 is formed and the performance test (e.g., the electrical die sorting process) is performed using the solder layer 150, thereby enhancing productivity of the performance test. The pad 120 and the insulation structure 140 respectively having a flat outer surface are formed by the removing process of the solder layer 150 performed after the performance test, thereby enhancing performance of the semiconductor chip 10 or a semiconductor package 100. That is, productivity of the semiconductor chip 10 or the semiconductor package 100 having enhanced performance may be enhanced.

In FIG. 5A to FIG. 5F, it is illustrated as an example that the pad 120 includes the interconnection pad 122 and the capping pad 124, but the example embodiments are not limited thereto. The manufacturing method according to the example embodiments may be applied to a case that the pad 120 includes a singly pad.

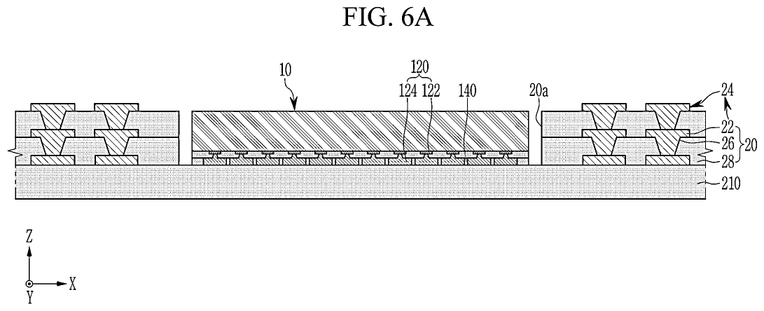

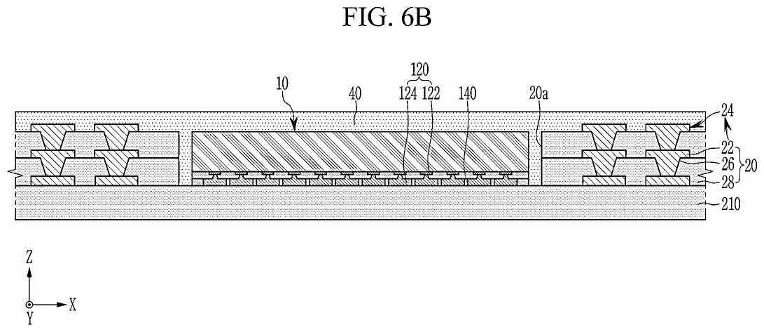

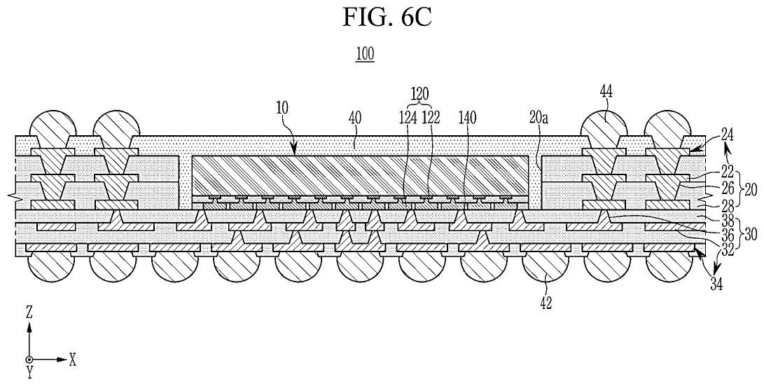

A manufacturing method of a semiconductor package 100 for packing the semiconductor chip 10 will be described with reference to FIG. 6A to FIG. 6C. For a clear understanding, in FIG. 6A to FIG. 60, a manufacturing method of a semiconductor package 100 is briefly illustrated.

FIG. 6A to FIG. 6C are cross-sectional views illustrating a manufacturing method of a semiconductor package according to some example embodiments.

As illustrated in FIG. 6A, a frame portion 20 including a space portion 20a and a frame redistribution portion is attached on a first carrier substrate 210, and a semiconductor chip 10 is attached on the first carrier substrate 210 in the space portion 20a. For example, the first carrier substrate 210 may include an adhesive material layer including an adhesive material on a surface to which the frame portion 20 is attached.

Subsequently, as illustrated in FIG. 6B, a molding portion 40 covering the semiconductor chip 10 and the frame portion 20 while filling the space portion 20a may be formed on the first carrier substrate 210 may be formed. In this instance, the insulation structure 140 may prevent, suppress, or reduce in likelihood the molding portion 40 from flowing into a side of the capping pad 124.

In some example embodiments, a second carrier substrate may be attached on the molding portion 40. For example, the second carrier substrate may be a semiconductor substrate or an insulation substrate. However, the example embodiments are not limited to a material of the second carrier substrate.

Subsequently, as illustrated in FIG. 6C, the first carrier substrate 210 may be removed and a redistribution portion 30 may be formed. The redistribution portion 30 is formed on a pad 120 having a flat outer surface and an insulation structure 140 having a flat outer surface, and thus, stability in the manufacturing of the redistribution portion 30 may be enhanced. Accordingly, a yield of the redistribution portion 30 may be enhanced and a fine pitch may be achieved. The second carrier substrate may be removed, and a first interconnection member 42 and a second interconnection member 44 may be formed.

According to some example embodiments, the capping pad 124 or the semiconductor chip 10 may be stably protected by the insulation structure 140 in a manufacturing process. The redistribution portion 30 is formed on the pad 120 having the flat outer surface and the insulation structure 140 having the flat outer surface and thus a yield of the redistribution portion 30 may be enhanced and a fine pitch may be achieved.

The manufacturing method of the semiconductor package 100 with reference to FIG. 6A to FIG. 6C is an example for a clear understanding, but the example embodiments are not limited thereto. Therefore, the manufacturing method of the semiconductor package 100 may be variously modified.

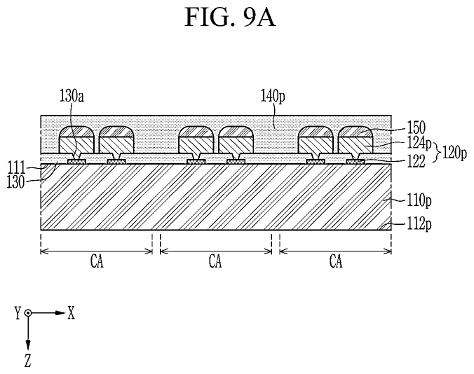

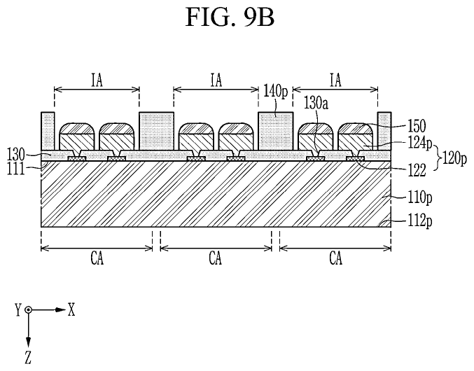

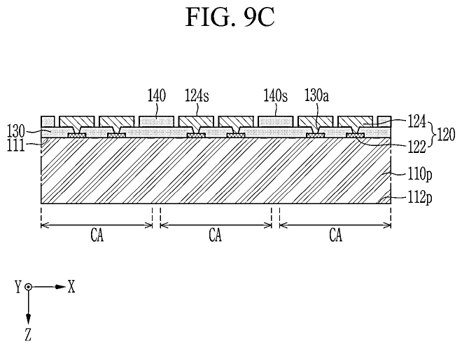

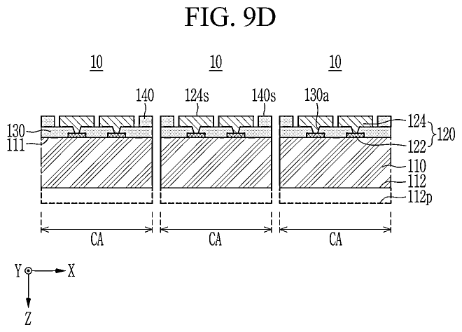

Hereinafter, a semiconductor chip 10 included in a semiconductor package and a manufacturing method of the semiconductor chip 10 according to some example embodiments will be described in detail with reference to FIG. 7, FIG. 8, and FIG. 9A to FIG. 9D. To the extent that an element is not described in detail below, it may be understood that the element is at least similar to a corresponding element that has been described elsewhere within the present disclosure. A portion which is not described in the above will be described in detail.

FIG. 7 is a cross-sectional view illustrating a semiconductor chip 10 included in a semiconductor package 100 according to some example embodiments. FIG. 8 is a plan view illustrating a first surface 101 of the semiconductor chip 10 illustrated in FIG. 7.

Referring to FIG. 7 and FIG. 8, in some example embodiments, an insulation structure 140 may be partially in an edge region EA along an edge of the semiconductor chip 10 on an insulation layer 130. For example, the insulation structure 140 is not provided on an inner region IA where a capping pad 124 is positioned, but the insulation structure 140 is provided in the edge region EA. In this instance, the inner region IA where the capping pad 124 is positioned may include a region formed by connecting outer edges of a plurality of capping pads 124. For example, an edge of the inner region IA may be at an outside of the outer edges of the plurality of the capping pad 124 and may be entirely spaced apart from an edge of the semiconductor chip 10.

Thereby, the insulation structure 140 is in the edge region EA of the semiconductor chip 10, and an edge of the semiconductor chip 10 may be stably protected. The insulation structure 140 is not provided on the inner region IA and an empty space may be between the capping pads 124, thereby enhancing structural stability even when thermal expansion or the like is generated.

For example, the insulation structure 140 may include a photosensitive material such as a PID material. For example, the photosensitive material may include photosensitive polyimide (PSPI), or the like, but the example embodiments are not limited thereto. When the insulation structure 140 includes the photosensitive material, a patterning process of the insulation structure 140 may be easy such that the insulation structure 140 is positioned in the edge region EA, but is not in the inner region IA. However, the example embodiments are not limited thereto, and a material of the insulation structure 140 may be variously modified.

In FIG. 8, it is illustrated as an example that the semiconductor chip 10 has the same length in a first direction (an X-axis direction in the drawing) and in a second direction (a Y-axis direction in the drawing), and an inner region IA is at a central portion of the semiconductor chip 10 to have a symmetrical structure. However, a shape or an arrangement of the semiconductor chip 10, a shape or an arrangement of the inner region IA, or the like may be variously modified.

In FIG. 8, it is illustrated as an example that the insulation structure 140 has a uniform width and is along an entire edge of the semiconductor chip 10. In some example embodiments, the insulation structure 140 may include portions having different widths, or may be along a partial portion of the edge of the semiconductor chip 10 while may be not on the other edge. Other various modifications are possible.

A manufacturing method of the semiconductor chip 10 included in the semiconductor package 100 according to some example embodiments will be described in detail with reference to FIG. 9A to FIG. 9D.

FIG. 9A to FIG. 9D are cross-sectional views illustrating a manufacturing method of a semiconductor chip according to some example embodiments. In FIG. 9A to FIG. 9D, it is illustrated as some example embodiments that a plurality of semiconductor chips 10 are formed to correspond to a plurality of chip regions CA on a preliminary semiconductor substrate 110p, and then, a plurality of semiconductor chip 10 are formed by a cutting process of a semiconductor substrate 110. For simple illustration and a clear understanding, a semiconductor chip 10 in a chip region CA is simply illustrated in FIG. 9A to FIG. 9D.

First, as illustrated in FIG. 9A, an interconnection pad 122, an insulation layer 130, and a preliminary capping pad 124p may be formed on a first surface 111 of a preliminary semiconductor substrate 110p. The interconnection pad 122 and the preliminary capping pad 124p may be referred to as a preliminary pad 120p. A solder layer 150 may be formed on the preliminary pad 120p (e.g., the preliminary capping pad 124p), and an electrical die sorting process may be performed using the solder layer 150. An insulation portion 140p covering the solder layer 150 on the first surface 111 of the preliminary semiconductor substrate 110p. In some example embodiments, the insulation portion 140p may be formed by coating a photosensitive material. Unless otherwise described, the description referring to FIGS. 5A to 5D may be applied as it is.

Subsequently, as illustrated in FIG. 9B, a patterning process of the insulation portion 140p may be performed. For example, a partial portion of the insulation portion 140p corresponding the inner region IA where the preliminary pad 120p and/or the solder layer 150 is positioned in a plan view may be removed to expose the preliminary pad 120p and the solder layer 150. For the removing process of the partial portion of the insulation portion 140p in a plan view, various processes may be applied. For example, the patterning process of the insulation portion 140p may be performed by a photolithography process.

In the drawing, it is illustrated as an example that the insulation portion 140p is spaced apart from the preliminary pad 120p with a predetermined interval after the patterning process. Process margins are considered, but the example embodiments are not limited thereto. Therefore, at least a partial portion of the insulation portion 140p may be adjacent to or in contact with the preliminary pad 120p. Other various modifications are possible.

Subsequently, as illustrated in FIG. 9C, the solder layer 150, a partial portion of the insulation portion 140p (refer to FIG. 9B), and a partial portion of the preliminary pad 120p (refer to FIG. 9B) may be removed. More particularly, an entire portion of the solder layer 150 may be removed, and an outer portion of the insulation portion 140p and an outer portion of the preliminary pad 120p in a thickness direction (a Z-axis direction in the drawing) may be removed in the edge region. That is, the partial portion of the insulation portion 140p and the partial portion of the preliminary capping pad 124p positioned at an outer side in a thickness direction of the preliminary semiconductor substrate 110p (a Z-axis direction in the drawing).

In this instance, the removing process of the solder layer 150, the outer portion of the insulation portion 140p, and the outer portion of the preliminary pad 120p may be performed by a grinding process. When the grinding process is used, the solder layer 150 may be stably removed, and an insulation structure 140 having an outer surface 140s of a flat surface and a pad 120 (e.g., a capping pad 124) having an outer surface 124s of a flat surface 124s may be formed.

The outer surface 140s of the insulation structure 140 and the outer surface 124s of the pad 120 may be formed by the same removing process (e.g., the same grinding process). Thereby, the outer surface 140s of the insulation structure 140 and the outer surface 124s of the pad 120 may be substantially on the same plane. The outer surface 140s of the insulation structure 140 and the outer surface 124s of the pad 120 may have substantially the same surface properties. For example, the outer surface 140s of the insulation structure 140 and the outer surface 124s of the capping pad 124 may have the grinding wheel mark of the same or similar pattern, or may have the same or similar surface roughness (e.g., surface roughness with a difference less than 10%). In some example embodiments, a removing process configured to remove the grinding wheel mark at the outer surface 140s of the insulation structure 140 and the outer surface 124s of the capping pad 124 may be performed.

Subsequently, as illustrated in FIG. 9D, a backlap process configured to reduce a thickness of the preliminary semiconductor substrate 110p (refer to FIG. 9C) may be performed to form a semiconductor substrate 110, and the semiconductor substrate 110 is cut to form a plurality of semiconductor chips 10. For a clear understanding, in FIG. 9D, the preliminary surface 112p of the preliminary semiconductor substrate 110p is illustrated as a dotted line, and a second surface 112 of the semiconductor substrate 110 formed by the backlap process is illustrated as a solid line. The description referring to FIG. 5F may be applied to the backlap process and the cutting process.

According to the example embodiments, in the semiconductor chip 10 that does not include the solder layer 150 in a final structure, the solder layer 150 is formed and the performance test (e.g., the electrical die sorting process) is performed using the solder layer 150, thereby enhancing productivity of the performance test. The pad 120 and the insulation structure 140 respectively having a flat outer surface are formed by the removing process of the solder layer 150 performed after the performance test, thereby enhancing performance of the semiconductor chip 10 or a semiconductor package 100. That is, productivity of the semiconductor chip 10 or the semiconductor package 100 having enhanced performance may be enhanced.

In FIG. 9A to FIG. 9D, it is illustrated as an example that the pad 120 includes the interconnection pad 122 and the capping pad 124, but the example embodiments are not limited thereto. The manufacturing method according to the example embodiments may be applied to a case that the pad 120 includes a single pad.

While some example embodiments have been described in connection with what is presently considered to be some practical example embodiments, it is to be understood that the disclosure is not limited to the disclosed example embodiments, and that that the disclosure is intended to cover various modifications and equivalent arrangements included within the spirit and scope of the appended claims.

What is claimed is:

1. A semiconductor chip, comprising:
a semiconductor substrate;
an interconnection pad on a first surface of the semiconductor substrate;
an insulation layer on the first surface of the semiconductor substrate, the insulation layer defining an opening that exposes at least a partial portion of the interconnection pad;
a capping pad on the insulation layer, the capping pad being connected to the interconnection pad through the opening; and
an insulation structure at a periphery of the capping pad on the insulation layer.

2. The semiconductor chip of claim 1, wherein an outer surface of the insulation structure and an outer surface of the capping pad are on a same plane.

3. The semiconductor chip of claim 1, wherein each of an outer surface of the insulation structure and an outer surface of the capping pad includes a flat surface.

4. The semiconductor chip of claim 1, wherein an outer surface of the capping pad has a height variation of 1 μm or less, and
a height difference between the outer surface of the insulation structure and an outer surface of the capping pad is 1 μm or less.

5. The semiconductor chip of claim 1, wherein a height variation at an outer surface of the capping pad is smaller than a height variation at an inner surface of the capping pad adjacent to the insulation layer and the interconnection pad, or
a height variation at the outer surface of the capping pad is smaller than a thickness of the insulation layer or a thickness of the interconnection pad.

6. The semiconductor chip of claim 1, wherein the capping pad includes a first portion that fills the opening and is connected to the interconnection pad and a second portion on the insulation layer, and
a thickness of the second portion is larger than a thickness of the insulation layer, a thickness of the interconnection pad, or a sum of the thickness of the insulation layer and the thickness of the interconnection pad.

7. The semiconductor chip of claim 1, wherein the capping pad includes a first portion that fills the opening and is connected to the interconnection pad and a second portion on the insulation layer, and
a thickness of the second portion is 5 μm to 15 μm.

8. The semiconductor chip of claim 1, wherein the insulation structure is at an entire region other than the capping pad on the insulation layer.

9. The semiconductor chip of claim 1, wherein the insulation structure is partially in an edge region that is along an edge of the semiconductor chip at an outside of the capping pad.

10. The semiconductor chip of claim 1, wherein the insulation structure includes a photosensitive material or an epoxy mold compound (EMC).

11. The semiconductor chip of claim 1, wherein the semiconductor chip is used for a fan-out panel level package (FoPLP).

12. A semiconductor package, comprising:
a redistribution portion; and
a semiconductor chip on the redistribution portion,
wherein the semiconductor chip includes:
a semiconductor substrate;
an interconnection pad on a first surface of the semiconductor substrate;
an insulation layer on the first surface of the semiconductor substrate, the insulation layer defining an opening that exposes at least a partial portion of the interconnection pad;
a capping pad on the insulation layer, the capping pad being connected to the interconnection pad through the opening and to the redistribution portion; and
an insulation structure at a periphery of the capping pad on the insulation layer, the insulation structure being adjacent to the redistribution portion.

13. A method of manufacturing a semiconductor chip, comprising:
forming a preliminary pad on a first surface of a semiconductor substrate;
forming a solder layer on the preliminary pad;
performing an electrical die sorting (EDS) process using the solder layer;
forming an insulation portion covering the solder layer on the first surface of the semiconductor substrate; and
removing the solder layer, an outer portion of the insulation portion, and an outer portion of the preliminary pad.

14. The manufacturing method of claim 13, wherein the removing is performed by a grinding process,
in the removing, an insulation structure having a flat outer surface and a pad having a flat outer surface are formed.

15. The manufacturing method of claim 14 wherein the insulation portion includes a photosensitive material or an epoxy mold compound (EMC).

16. The manufacturing method of claim 13, further comprising:
a patterning process configured to expose the preliminary pad and the solder layer by partially removing an inner region of the insulation portion where the preliminary pad and the solder layer are positioned, between the forming of the insulation portion and the removing.

17. The manufacturing method of claim 16, wherein the removing is performed by a grinding process,
in the removing, an insulation structure having a flat outer surface and partially positioned at an edge region and a pad having a flat outer surface are formed.

18. The manufacturing method of claim 16, wherein the insulation portion includes a photosensitive material.

19. The manufacturing method of claim 13, further comprising after the removing:
a backlap configured to reducing a thickness of the semiconductor substrate; and
cutting the semiconductor substrate to form a plurality of semiconductor chips.

20. The manufacturing method of claim 19, wherein the semiconductor chip is used for a fan-out panel level package (FoPLP).
